(19) United States
(12) Patent Application Publication
(10) Pub. No.: US 2022/0051748 A1
(43) Pub. Date: Feb. 17, 2022

(54) EXECUTION METHOD OF FIRMWARE CODE, MEMORY STORAGE DEVICE AND MEMORY CONTROL CIRCUIT UNIT

(71) Applicant: PHISON ELECTRONICS CORP., Miaoli (TW)

(72) Inventors: Yi-Feng Li, Miaoli County (TW); Chun-Yu Ling, Miaoli (TW)

(73) Assignee: PHISON ELECTRONICS CORP., Miaoli (TW)

(21) Appl. No.: 17/033,684

(22) Filed: Sep. 26, 2020

(30) Foreign Application Priority Data
Aug. 13, 2020 (TW) 109127454

(51) Int. Cl. G11C 29/00; G11C 7/20; G11C 7/22

(52) U.S. Cl. CPC G11C 29/72; G11C 7/22; G11C 7/20; G11C 29/787

(57) ABSTRACT

An execution method of a firmware code, a memory storage device and a memory control circuit unit are disclosed. The method includes: executing a firmware code in a read only memory; after executing a first part of the firmware code, querying reference information in a reference memory according to index information in the firmware code; and determining, according to the reference information, to continuously execute a second part of the firmware code or switch to execute a replacement program code in the reference memory, so as to complete a startup procedure.

### CROSS-REFERENCE TO RELATED APPLICATION

This application claims the priority benefit of Taiwan application Ser. No. 109127454, filed on Aug. 13, 2020. The entirety of the above-mentioned patent application is hereby incorporated by reference herein and made a part of this specification.

### BACKGROUND

### Technical Field

The disclosure relates to a memory management technique, and more particularly, to an execution method of a firmware code, a memory storage device and a memory control circuit unit.

### Description of Related Art

The markets of digital cameras, cellular phones, and MP3 players have expanded rapidly in recent years, resulting in escalated demand for storage media by consumers. The characteristics of data non-volatility, low power consumption, and compact size make a rewritable non-volatile memory module (e.g., flash memory) ideal to be built in the portable multi-media devices as cited above.

Most memory storage devices or their control chips store a firmware code for booting. When booting, the control chip of the memory storage device can execute the firmware code to complete a boot process or a startup process such as system initialization. Generally speaking, before the memory storage device or its control chip is shipped from the factory, the firmware code will be pre-burned in the read only memory of the memory storage device or its control chip to prevent the device from being modified by the user during operation. However, this approach also causes the firmware code in the read only memory to be unable to be modified or updated. If someone want to update the firmware code in the read only memory, the manufacturing process of the read only memory needs to be redone.

Nothing herein should be construed as an admission of knowledge in the prior art of any portion of the present disclosure. Furthermore, citation or identification of any document in this application is not an admission that such document is available as prior art to the present disclosure, or that any reference forms a part of the common general knowledge in the art.

### SUMMARY

The disclosure provides a firmware code execution method, a memory storage device and a memory control circuit unit, which can dynamically adjust an execution result of a firmware code that cannot be modified in a read only memory.

An execution method of a firmware code for a memory storage device is provided according to an exemplary embodiment of the disclosure. The memory storage device comprises a read only memory and a reference memory. The execution method of the firmware code comprises: executing the firmware code in the read only memory; after executing a first part of the firmware code, querying reference information in the reference memory according to index information in the firmware code; and determining, according to the reference information, to continuously execute a second part of the firmware code or switch to execute a replacement program code in the reference memory, so as to complete a startup procedure.

A memory storage device is provided according to an exemplary embodiment of the disclosure. The memory storage device comprises a host interface, a rewritable non-volatile memory module and a memory control circuit unit. The host interface is configured to couple to a host system. The memory control circuit unit is coupled to the host interface and the rewritable non-volatile memory module. The memory control circuit unit is configured to execute a firmware code in a read only memory. After executing a first part of the firmware code, the memory control circuit unit is further configured to query reference information in a reference memory according to index information in the firmware code. The memory control circuit unit is further configured to determine, according to the reference information, to continuously execute a second part of the firmware code or switch to execute a replacement program code in the reference memory, so as to complete a startup procedure.

A memory control circuit unit is provided according to an exemplary embodiment of the disclosure. The memory control circuit unit comprises a read only memory, a reference memory and a memory control circuit. The read only memory is configured to store a firmware code. The reference memory is configured to store reference information. The memory control circuit is coupled to the read only memory and the reference memory. The memory control circuit is configured to execute the firmware code in the read only memory. After executing a first part of the firmware code, the memory control circuit is further configured to query reference information in the reference memory according to index information in the firmware code. The memory control circuit is further configured to determine, according to the reference information, to continuously execute a second part of the firmware code or switch to execute a replacement program code in the reference memory, so as to complete a startup procedure.

Based on the above, after executing the first part of the firmware code, the reference information in the reference memory can be queried according to the index information in the firmware code. Then, according to the reference information, it can be determined to continue to execute the second part of the firmware code or switch to execute the replacement program code in the reference memory to complete the startup procedure. As a result, there is no need to redo the manufacturing process of the read only memory, and the execution result of the firmware code in the read only memory can also be dynamically adjusted, thereby improving the using flexibility of the memory storage device (or memory control circuit unit) and/or extending the service life of the memory storage device (or memory control circuit unit).

It should be understood, however, that this Summary may not contain all of the aspects and embodiments of the present disclosure, is not meant to be limiting or restrictive in any manner, and that the disclosure as disclosed herein is and will be understood by those of ordinary skill in the art to encompass obvious improvements and modifications thereto.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a memory storage device according to an exemplary embodiment of the present disclosure.

FIG. 2 is a schematic diagram of adjusting the execution of the firmware code according to an exemplary embodiment of the present disclosure.

FIG. 3 is a schematic diagram of a memory storage device according to an exemplary embodiment of the present disclosure.

FIG. 4 is a flowchart of an execution method of a firmware code according to an exemplary embodiment of the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Embodiments of the present disclosure may comprise any one or more of the novel features described herein, including in the Detailed Description, and/or shown in the drawings.

As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”), “one or more” and “at least one” can be used interchangeably herein.

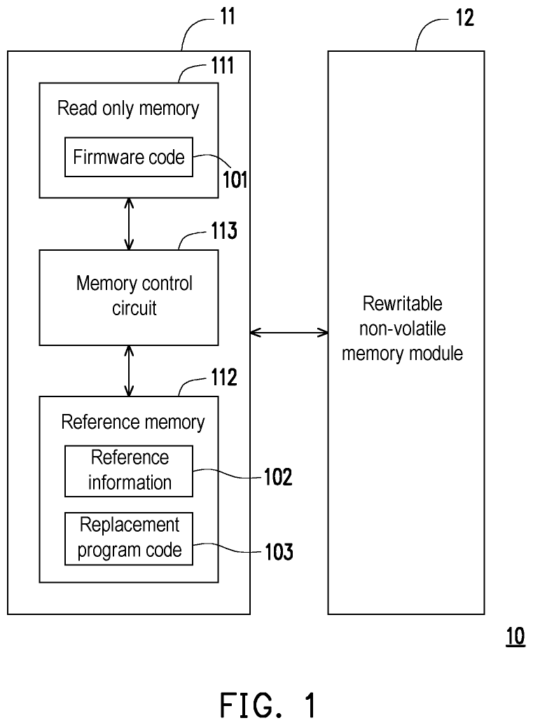

FIG. 1 is a schematic diagram of a memory storage device according to an exemplary embodiment of the present disclosure. Please refer to FIG. 1, the memory storage device 10 includes a memory control circuit unit 11 and a rewritable non-volatile memory module 12. The memory control circuit unit 11 is coupled to the rewritable non-volatile memory module 12. The memory control circuit unit 11 may include at least one control chip and used to control the rewritable non-volatile memory module 12. In an exemplary embodiment, the memory control circuit unit 11 can also be configured to control the entire or partial operation of the memory storage device 10. The rewritable non-volatile memory module 12 may include any type of non-volatile storage unit and used to store data non-volatilely.

In an exemplary embodiment, the memory control circuit unit 11 includes a read only memory (ROM) 111, a reference memory 112, and a memory control circuit 113. The read only memory 111 is configured to store data non-volatilely. In particular, data in the read only memory 111 is burned before the memory storage device 10 or the memory control circuit unit 11 leaving the factory, and such data cannot be modified after the memory storage device 10 or the memory control circuit unit 11 leaves the factory.

The reference memory 112 is configured to store data volatile or non-volatile.

Compared with the read only memory 111, data stored in the reference memory 112 can be modified after the memory storage device 10 or the memory control circuit unit 11 leaves the factory. Therefore, after the memory storage device 10 or the memory control circuit unit 11 is shipped from the factory, the data in the reference memory 112 can be used to reinforce or update the data in the read only memory 111 that cannot be modified.

The memory control circuit 113 is coupled to the read only memory 111 and the reference memory 112. The memory control circuit 113 is configured to access the read only memory 111 and the reference memory 112 and may send control commands to control the rewritable non-volatile memory module 12 (or the memory storage device 10) according to the access result of the read only memory 111 (and the reference memory 112). For example, the memory control circuit 113 may include a memory controller, or other programmable general-purpose or special-purpose microprocessors, digital signal processors (DSP), programmable controllers, application specific integrated circuits (ASIC), programmable logical devices (PLD) or other similar devices or a combination of these devices.

In an exemplary embodiment, data stored in the read only memory 111 includes a firmware code 101. When a boot signal is detected, the memory control circuit 113 can read and execute the firmware code 101 from the read only memory 111 to perform a startup procedure. For example, the startup procedure can be a boot procedure (also called an initialization procedure) or a wake-up procedure. The boot procedure is configured to boot the memory storage device 10. The wake-up procedure is configured to wake the memory storage device 10 from standby, hibernation or sleep states. In the startup procedure, in response to the operation of the firmware code 101, the memory control circuit 113 can send at least one access command to the rewritable non-volatile memory module 12 to read data from a specific physical address in the rewritable non-volatile memory module 12 and/or write data to a specific physical address in rewritable non-volatile memory module 12.

In an exemplary embodiment, data stored in the reference memory 112 includes reference information 102 and a replacement program code 103. After executing a part (also referred to as a first part) of the firmware code 101, the memory control circuit 113 can query the reference information 102 in the reference memory 112 according to index information in the firmware code 101. The memory control circuit 113 may determine to continue to execute another part (also referred to as a second part) of the firmware code 101 or switch to execute the replacement program code 103 in the reference memory 112 according to the reference information 102, so as to complete the startup procedure. It should be noted that the second part of the firmware code 101 is preset to be continued after the first part of the firmware code 101. Therefore, if switching to the execution of replacement program code 103, the second part of firmware code 101 can be skipped and not be executed.

It is assumed that the firmware code 101 originally burned in the read only memory 111 is used for a specific type of memory storage device or the firmware code 101 has an error. Traditionally, if someone wants to make the firmware code 101 compatible with other types of memory storage devices or correct errors in the firmware code 101, it is needed to redo the process to burn a new firmware code to the read only memory 111; however, such an approach will increase manufacturing costs. In an exemplary embodiment, by switching to the execution of the replacement program code 103 (and skipping the second part of firmware code 101), the original execution result of the firmware code 101 can be changed to achieve the same or similar results as directly updating the firmware code 101.

In an exemplary embodiment, it is assumed that at least one first access command can be sent in response to the execution of the second part of the firmware code 101. The at least one first access command can instruct an access to a physical address A. After switching to the execution of the replacement program code 103, at least one second access command can be sent in response to the execution of the replacement program code 103. The at least one second access command can instruct an access to a physical address B. The physical address A is different from the physical address B.

In an exemplary embodiment, it is assumed that at least one third access command can be sent in response to the execution of the second part of the firmware code 101. The at least one third access command may instruct a write of data C to the physical address A of the rewritable non-volatile memory module 12. After switching to the execution of the replacement program code 103, at least one fourth access command can be sent in response to the execution of the replacement program code 103. The at least one fourth access command can instruct a write of data D to the physical address A (or the physical address B) of the rewritable non-volatile memory module 12. The data D is different from the data C.

In an exemplary embodiment, different control commands may be sent in response to the execution of the second part of the firmware code 101 and in response to the execution of the replacement program code 103. The different control commands can be used to perform different controls or configurations on the electronic components in the memory storage device 10. Alternatively, in an exemplary embodiment, in response to the execution of the second part of the firmware code 101 and in response to the execution of the replacement program code 103, at least part of the system information of the memory storage device 10 may be configured differently during the startup process, etc., the present disclosure is not limited thereto.

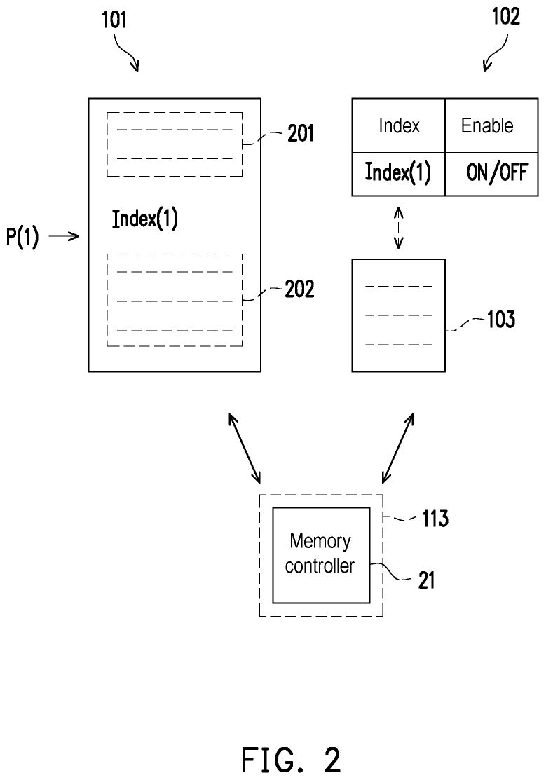

FIG. 2 is a schematic diagram of adjusting the execution of the firmware code according to an exemplary embodiment of the present disclosure. Referring to FIG. 1 and FIG. 2, in an exemplary embodiment, the memory control circuit 113 includes a memory controller 21. The firmware code 101 includes firmware codes 201 and 202. The firmware code 201 is the first part of the firmware code 101. The firmware code 202 is the second part of the firmware code 101. The firmware code 202 is continued after firmware code 201, and index information Index(1) is inserted between the firmware codes 201 and 202.

When a boot signal or a startup signal is detected, the memory controller 21 can execute the firmware code 101 to execute the startup procedure. In the startup procedure, the memory controller 21 can execute the firmware code 201 first. After executing the firmware code 201, when the execution reaches a position P(1), the memory controller 21 can read the index information Index(1). The memory controller 21 can query the reference information 102 from the reference memory 112 according to the index information Index(1) and determine, according to the query result, whether to continue executing the firmware code 202 or switch to executing the replacement program code 103 in the reference memory 112.

In an exemplary embodiment, it is assumed the query result reflects that identification information corresponding to the index information Index(1) in the reference information 102 is first identification information (for example, enable information being OFF). After executing the firmware code 201, the memory controller 21 can continue to execute the firmware code 202 according to the query result. In other words, in this exemplary embodiment, the memory controller 21 will continuously execute the firmware codes 201 and 202 in the firmware code 101.

In an exemplary embodiment, it is assumed the query result reflects that the identification information corresponding to the index information Index(1) in the reference information 102 is second identification information (for example, the enable information being ON). After executing the firmware code 201, the memory controller 21 can switch to execute the replacement program code 103 in the reference memory 112 according to the query result. In other words, in this exemplary embodiment, the memory controller 21 will continuously execute the firmware code 201 in the firmware code 101 and the replacement program code 103 in the reference memory 112. In addition, in this exemplary embodiment, the firmware code 202 will be skipped and not be executed.

It should be noted that although the exemplary embodiment of FIG. 2 only divides the firmware code into two parts. However, in another exemplary embodiment, the firmware code can also be divided into more parts, and index information can be inserted between any two consecutive parts. During the execution of the firmware code, if specific index information is read, the index information can be used to query the reference information and it is determined, according to the query result, whether to execute the subsequent part of the firmware code or switch to executing the corresponding replacement program code in the reference memory.

In an exemplary embodiment, the reference memory 112 of FIG. 1 includes an electronic fuse (eFuse) structure. The reference information 102 and/or the replacement program code 103 can be stored in this electronic fuse structure.

In an exemplary embodiment, the reference memory 112 of FIG. 1 includes random access memory (RAM). The reference information 102 and/or the replacement program code 103 can be stored in this random access memory.

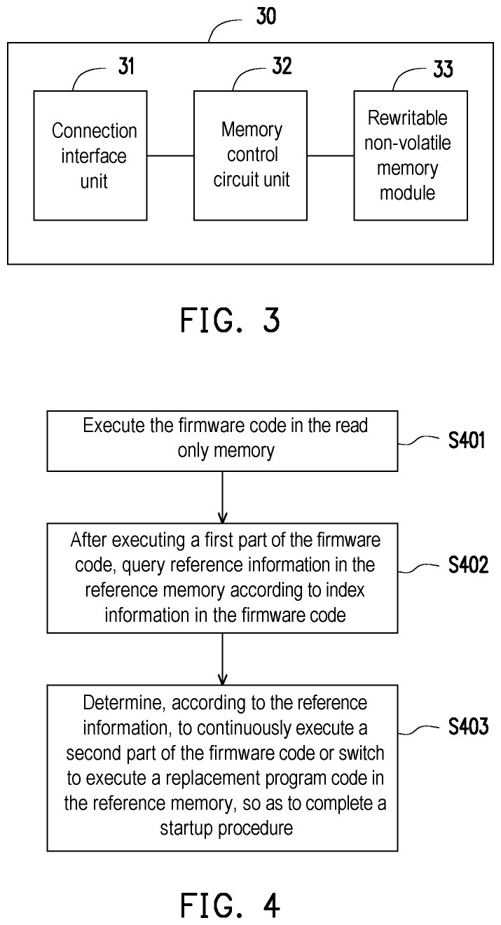

FIG. 3 is a schematic diagram of a memory storage device according to an exemplary embodiment of the present disclosure. Please refer to FIG. 3, a memory storage device 30 includes a connection interface unit 31, a memory control circuit unit 32, and a rewritable non-volatile memory module 33. It should be noted that the memory control circuit unit 32 may include the memory control circuit unit 11 of FIG. 1, and the rewritable non-volatile memory module 33 may include the rewritable non-volatile memory module 12 of FIG. 1.

The connection interface unit 31 is configured to couple to the memory storage device 30 to a host system. In this exemplary embodiment, the connection interface unit 31 is compatible with a SATA (Serial Advanced Technology Attachment) standard. Nevertheless, it should be understood that the disclosure is not limited in this regard. The connection interface unit 31 may also be compatible with a PATA (Parallel Advanced Technology Attachment) standard, an IEEE (Institute of Electrical and Electronic Engineers) 1394 standard, a PCI Express (Peripheral Component Interconnect Express) interface standard, a USB (Universal Serial Bus) standard, a SD interface standard, a UHS-I (Ultra High Speed-I) interface standard, a UHS-II (Ultra High Speed-II) interface standard, a MS (Memory Stick) interface standard, a MCP interface standard, a MMC interface standard, an eMMC interface standard, a UFS (Universal Flash Storage) interface standard, an eMCP interface standard, a CF interface standard, an IDE (Integrated Device Electronics) interface standard or other suitable standards. The connection interface unit 31 and the memory control circuit unit 32 may be packaged into one chip, or the connection interface unit 31 is distributed outside of a chip containing the memory control circuit unit 32.

The memory control circuit unit 32 is configured to execute a plurality of logic gates or control commands which are implemented in a hardware form or in a firmware form and perform operations of writing, reading or erasing data in the rewritable non-volatile memory module 33 according to the commands of the host system.

The rewritable non-volatile memory module 33 is coupled to the memory control circuit unit 32 and configured to store data written from the host system 61. The rewritable non-volatile memory module 33 may be a SLC (Single Level Cell) NAND flash memory module (i.e., a flash memory module capable of storing one bit in one memory cell), a MLC (Multi Level Cell) NAND flash memory module (i.e., a flash memory module capable of storing two bits in one memory cell), a TLC (Triple Level Cell) NAND flash memory module (i.e., a flash memory module capable of storing three bits in one memory cell), a QLC (Quad Level Cell) NAND-type flash memory module (i.e., a flash memory module capable of storing four bits in one memory cell), other flash memory modules or other memory modules having the same features.

In the rewritable non-volatile memory module 33, one or more bits are stored by changing a voltage (hereinafter, also known as a threshold voltage) of each of the memory cells. More specifically, in each of the memory cells, a charge trapping layer is provided between a control gate and a channel. Amount of electrons in the charge trapping layer may be changed by applying a write voltage to the control gate thereby changing the threshold voltage of the memory cell. This operation of changing the threshold voltage of the memory cell is also known as “writing data into the memory cell” or “programming the memory cell”. By changing the threshold voltage, each of the memory cells in the rewritable non-volatile memory module 33 can have a plurality of storage states. The storage state to which the memory cell belongs may be determined by applying a read voltage to the memory cell, so as to obtain the one or more bits stored in the memory cell.

In this exemplary embodiment, the memory cells of the rewritable non-volatile memory module 33 can constitute a plurality of physical programming units, and the physical programming units can constitute a plurality of physical erasing units. Specifically, the memory cells on the same word line can constitute one or more of the physical programming units. If each of the memory cells can store two or more bits, the physical programming units on the same word line can be at least classified into a lower physical programming unit and an upper physical programming unit. For instance, a least significant bit (LSB) of one memory cell belongs to the lower physical programming unit, and a most significant bit (MSB) of one memory cell belongs to the upper physical programming unit. Generally, in the MLC NAND flash memory, a writing speed of the lower physical programming unit is higher than a writing speed of the upper physical programming unit, and/or a reliability of the lower physical programming unit is higher than a reliability of the upper physical programming unit.

In the present exemplary embodiment, the physical programming unit is the minimum unit for programming. That is, the physical programming unit is the minimum unit for writing data. For example, the physical programming unit may be a physical page or a physical sector. If the physical programming unit is the physical page, these physical programming units can include a data bit area and a redundancy bit area. The data bit area contains multiple physical sectors configured to store user data, and the redundant bit area is configured to store system data (e.g., management data such as an error correcting code, etc.). In this exemplary embodiment, the data bit area contains 32 physical sectors, and a size of each physical sector is 512 bytes (B). However, in other exemplary embodiments, the data bit area may also include 8, 16 physical sectors or different number (more or less) of the physical sectors, and the size of each physical sector may also be greater or smaller. On the other hand, the physical erasing unit is the minimum unit for erasing. Namely, each physical erasing unit contains the least number of memory cells to be erased together. For instance, the physical erasing unit is a physical block.

FIG. 4 is a flowchart of an execution method of a firmware code according to an exemplary embodiment of the present disclosure. Please refer to FIG. 4, in a step S401, a firmware code in the read only memory is executed. In a step S402, after executing a first part of the firmware code, reference information in the reference memory is queried according to index information in the firmware code. In a step S403, it is determined, according to the reference information, to continuously execute a second part of the firmware code or switch to execute a replacement program code in the reference memory, so as to complete a startup procedure.

Nevertheless, steps depicted in FIG. 4 are described in detail as above so that related description thereof is omitted hereinafter. It should be noted that, the steps depicted in FIG. 4 may be implemented as a plurality of program codes or circuits, which are not particularly limited in the disclosure. Moreover, the method disclosed in FIG. 4 may be implemented by reference with above exemplary embodiments, or may be implemented separately, which are not particularly limited in the disclosure.

Based on the above, after executing the first part of the firmware code, the reference information in the reference memory can be queried according to the index information in the firmware code. Then, according to the reference information, it can be determined to continue to execute the second part of the firmware code or switch to execute the replacement program code in the reference memory to complete the startup procedure. As a result, there is no need to redo the manufacturing process of the read only memory, and the execution result of the firmware code in the read only memory can also be dynamically adjusted, thereby improving the using flexibility of the memory storage device (or memory control circuit unit) and/or extending the service life of the memory storage device (or memory control circuit unit).

The previously described exemplary embodiments of the present disclosure have the advantages aforementioned, wherein the advantages aforementioned not required in all versions of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. An execution method of a firmware code for a memory storage device, wherein the memory storage device comprises a read only memory and a reference memory, and the execution method of the firmware code comprises:
executing the firmware code in the read only memory;
after executing a first part of the firmware code, querying reference information in the reference memory according to index information in the firmware code; and
determining, according to the reference information, to continuously execute a second part of the firmware code or switch to execute a replacement program code in the reference memory, so as to complete a startup procedure.

2. The execution method of the firmware code according to claim 1, wherein the reference memory comprises an electronic fuse structure.

3. The execution method of the firmware code according to claim 1, wherein the reference memory comprises a random access memory.

4. The execution method of the firmware code according to claim 1, wherein a step of determining, according to the reference information, to continuously execute the second part of the firmware code or switch to execute the replacement program code in the reference memory comprises:
if the reference information comprises first identification information, continuously executing the second part of the firmware code after executing the first part of the firmware code; and
if the reference information comprises second identification information, switching to execute the replacement program code in the reference memory after executing the first part of the firmware code.

5. The execution method of the firmware code according to claim 1, wherein the startup procedure comprise turning on or waking up the memory storage device.

6. A memory storage device, comprising:
a host interface, configured to couple to a host system;
a rewritable non-volatile memory module; and
a memory control circuit unit, coupled to the host interface and the rewritable non-volatile memory module,
wherein the memory control circuit unit is configured to execute a firmware code in a read only memory,
after executing a first part of the firmware code, the memory control circuit unit is further configured to query reference information in a reference memory according to index information in the firmware code, and
the memory control circuit unit is further configured to determine, according to the reference information, to continuously execute a second part of the firmware code or switch to execute a replacement program code in the reference memory, so as to complete a startup procedure.

7. The memory storage device according to claim 6, wherein the reference memory comprises an electronic fuse structure.

8. The memory storage device according to claim 6, wherein the reference memory comprises a random access memory.

9. The memory storage device according to claim 6, wherein an operation of determining, according to the reference information, to continuously execute the second part of the firmware code or switch to execute the replacement program code in the reference memory comprises:
if the reference information comprises first identification information, continuously executing the second part of the firmware code after executing the first part of the firmware code; and
if the reference information comprises second identification information, switching to execute the replacement program code in the reference memory after executing the first part of the firmware code.

10. The memory storage device according to claim 6, wherein the startup procedure comprise turning on or waking up the memory storage device.

11. A memory control circuit unit, comprising:
a read only memory, configured to store a firmware code;
a reference memory, configured to store reference information;
a memory control circuit, coupled to the read only memory and the reference memory,
wherein the memory control circuit is configured to execute the firmware code in the read only memory,
after executing a first part of the firmware code, the memory control circuit is further configured to query the reference information in the reference memory according to index information in the firmware code, and
the memory control circuit is further configured to determine, according to the reference information, to continuously execute a second part of the firmware code or switch to execute a replacement program code in the reference memory, so as to complete a startup procedure.

12. The memory control circuit unit according to claim 11, wherein the reference memory comprises an electronic fuse structure.

13. The memory control circuit unit according to claim 11, wherein the reference memory comprises a random access memory.

14. The memory control circuit unit according to claim 11, wherein an operation of determining, according to the reference information, to continuously execute the second part of the firmware code or switch to execute the replacement program code in the reference memory comprises:
if the reference information comprises first identification information, continuously executing the second part of the firmware code after executing the first part of the firmware code; and
if the reference information comprises second identification information, switching to execute the replacement program code in the reference memory after executing the first part of the firmware code.

15. The memory control circuit unit according to claim 11, wherein the startup procedure comprise turning on or waking up a memory storage device.
